(19) United States
(12) Patent Application Publication
(10) Pub. No.: US 2023/0038880 A1
(43) Pub. Date: Feb. 9, 2023

(54) PROTECTIVE COATING FOR A SEMICONDUCTOR REACTION CHAMBER

(71) Applicant: Lam Research Corporation, Fremont, CA (US)

(72) Inventors: Alon Ganany, Portland, OR (US); Dustin Zachary Austin, Tigard, OR (US); Rachel Batzer, Tualatin, OR (US); Akhil Singhal, Beaverton, OR (US)

(21) Appl. No.: 17/759,096

(22) PCT Filed: Dec. 17, 2020
(86) PCT No.: PCT/US2020/065717

§ 371 Date: Jul. 19, 2022

Related U.S. Application Data
(60) Provisional application No. 62/965,049, filed on Jan. 23, 2020.

(51) Int. Cl. C23C 16/44; H01J 37/32

(52) U.S. Cl. CPC C23C 16/4404; C23C 16/4405; H01J 37/32495; C23C 16/52

(57) ABSTRACT

Processing methods and apparatus for depositing a protective layer on internal surfaces of a reaction chamber are provided. One method may include depositing, while no wafers are present in the reaction chamber having interior surfaces, a first layer of protective material onto the interior surfaces, the interior surfaces comprising a first material, processing, after the depositing the first layer, a portion of a batch of wafers within a reaction chamber, measuring an amount of the first material in the reaction chamber during processing the portion of the batch of wafers, or on one of the wafers in the portion of the batch of wafers, determining that the first amount exceeds a threshold, and depositing, in response to determining that the first amount exceeds the threshold and while no wafers are present in the reaction chamber, a second layer of protective material onto the interior surfaces of the reaction chamber.

### RELATED APPLICATIONS

A PCT Request Form is filed concurrently with this specification as part of the present application. Each application that the present application claims benefit of or priority to as identified in the concurrently filed PCT Request Form is incorporated by reference herein in its entirety and for all purposes.

### BACKGROUND

In some semiconductor processing operations, e.g., deposition, etching, and cleaning operations, the gases used in these operations may be corrosive to the interior surfaces of the reaction chamber in which the processing operations are performed. Over time, the interior surfaces of the reaction chamber may be etched or corroded beyond an acceptable threshold.

### SUMMARY

In some embodiments, a method may be provided. The method may include depositing, while no wafers are present in a reaction chamber having a plurality of interior surfaces, a first layer of protective material onto the plurality of interior surfaces of the reaction chamber and the plurality of interior surfaces may include a first material, processing, after depositing the first layer of protective material, a portion of a batch of wafers within a reaction chamber, measuring an amount of the first material in the reaction chamber during the processing the portion of the batch of wafers, or on one of the wafers in the portion of the batch of wafers, determining that the first amount exceeds a threshold, and depositing, in response to the determination that the first amount exceeds the threshold and while no wafers are present in the reaction chamber, a second layer of protective material onto the plurality of interior surfaces of the reaction chamber.

In some embodiments, the method may further include processing, after depositing the second layer of protective material, a second portion of the batch of wafers within the reaction chamber.

In some embodiments, the method may further include cleaning, before depositing the second layer of protective material, the reaction chamber.

In some such embodiments, the depositing the second layer of protective material may further include depositing the second layer of protective material onto the first layer of material and onto the plurality of interior surfaces of the reaction chamber.

In some embodiments, the measuring may further include measuring the amount of the first material in the reaction chamber during a processing operation during the processing the portion of the batch of wafers.

In some such embodiments, the measuring may further include measuring the amount of the first material in the reaction chamber during the processing operation by using a residual gas analyzer or a spectroscope.

In some embodiments, the measuring may further include measuring the amount of the first material on one of the wafers in the portion of the wafers.

In some embodiments, the protective material may include silicon oxide.

In some embodiments, the first material may include aluminum or an aluminum alloy.

In some embodiments, the processing may include etching operations.

In some embodiments, the processing may include deposition operations.

In some embodiments, the processing may not include a chamber cleaning operation.

In some embodiments, the depositing the protective material onto the plurality of interior surfaces of the reaction chamber may be performed by atomic layer deposition.

In some embodiments, a method may be provided. The method may include depositing, while no wafers are present in a reaction chamber, a layer of protective material onto a plurality of interior surfaces of the reaction chamber and the plurality of interior surfaces may include a first material, processing a portion of a batch of wafers within the reaction chamber, the processing uses a process gas that is capable of etching the first material of the plurality of interior surfaces at a first etch rate during the processing at a first set of processing conditions and the process gas etches the protective material at a second etch rate during the processing at the first set of processing conditions, and wherein the second etch rate is at least 20 times less than the first etch rate.

In some embodiments, the method may further include depositing, after processing the portion of the batch of wafers and while no wafers are present in the reaction chamber, a second layer of protective material onto the plurality of interior surfaces of the reaction chamber, and processing, after depositing the second layer of protective material, a second portion of the batch of wafers within the reaction chamber.

In some embodiments, the method may further include cleaning, before depositing the second layer of protective material, the reaction chamber.

In some such embodiments, the depositing the second layer of protective material may further include depositing the second layer of protective material onto the first layer of material and onto the plurality of interior surfaces of the reaction chamber.

In some embodiments, the second etch rate may be at least 100 times less than the first etch rate.

In some embodiments, the protective layer may include silicon oxide.

In some embodiments, the first material may include aluminum or aluminum alloy.

In some embodiments, the processing may include etching operations.

In some embodiments, the processing may include deposition operations.

In some embodiments, the processing may not include a chamber cleaning operation.

In some embodiments, the depositing the protective material may be performed by atomic layer deposition.

In some embodiments an apparatus for use in semiconductor processing may be provided. The apparatus may include a reaction chamber having a top with a top surface, side walls with wall surfaces, and a bottom with a bottom surface, and an internal volume partially defined by the top, the side walls, and the bottom, a substrate support having substrate support exterior surfaces, a showerhead having showerhead exterior surfaces, and a protective coating of material. The substrate support and the showerhead are positioned within the internal volume of the reaction chamber, the top surface, the wall surfaces, the bottom surface, the substrate support exterior surfaces, and the showerhead exterior surfaces are made of a first material that comprises a metal, and the protective coating is on and in direct contact with the top surface, the wall surfaces, the bottom surface, the substrate support exterior surfaces, and the showerhead exterior surfaces.

In some embodiments, the metal may be aluminum or an aluminum alloy.

In some embodiments, the protective coating may include silicon oxide.

In some embodiments, a process gas may be capable of etching the first material at a first etch rate during a processing operation under a first set or process conditions, the process gas may be capable of etching the protective material at a second etch rate during the processing operation under the first set or process conditions, and the second etch rate may be at least 20 times less than the first etch rate.

In some embodiments, the second etch rate may be at least 100 times less than the first etch rate.

These and other aspects are described further below with reference to the drawings.

### BRIEF DESCRIPTION OF THE DRAWINGS

FIG. 1A depicts a simplified exemplary view of a reaction chamber in which processes in accordance with the present disclosure may be implemented.

FIG. 1B depicts the reaction chamber of FIG. 1A with a layer of protective material deposited on the interior surfaces of the reaction chamber.

FIG. 2 depicts an example technique in accordance with the present disclosure.

FIG. 3 depicts another example technique in accordance with the present disclosure.

FIG. 4 depicts yet another example technique in accordance with the present disclosure.

FIG. 5 depicts a graphical representation of depositions of protective material on an interior reaction chamber surface.

FIG. 6 schematically shows an embodiment of a process station.

FIG. 7 shows a schematic view of an embodiment of a multi-station processing tool.

FIG. 8 depicts experimental data of aluminum measured on wafers after various amounts of etching and chamber cleans are performed in a reaction chamber having aluminum interior surfaces and a protective material deposited thereon.

FIG. 9 depicts other experimental data of aluminum measured on wafers after various amounts of etching are performed in a reaction chamber having aluminum interior surfaces and a protective coating deposited thereon.

### DETAILED DESCRIPTION

In the following description, numerous specific details are set forth to provide a thorough understanding of the presented embodiments. Embodiments disclosed herein may be practiced without some or all of these specific details. In other instances, well-known process operations have not been described in detail to not unnecessarily obscure the disclosed embodiments. Further, while the disclosed embodiments will be described in conjunction with specific embodiments, it will be understood that the specific embodiments are not intended to limit the disclosed embodiments.

In this application, the terms “wafer” and “substrate” are used interchangeably. A wafer or substrate used in the semiconductor device industry typically has a diameter of 200 mm, or 300 mm, or 450 mm. Unless otherwise stated, the processing details recited herein (e.g., flow rates, power levels, etc.) are relevant for processing 300 mm diameter substrates, or for treating chambers that are configured to process 300 mm diameter substrates, and can be scaled as appropriate for substrates or chambers of other sizes. The chambers described herein may be used to process work pieces that may be of various shapes, sizes, and materials. In addition to semiconductor wafers, other work pieces that may be processed in chambers prepared according to certain embodiments include various articles such as printed circuit boards, magnetic recording media, magnetic recording sensors, mirrors, optical elements, micro-mechanical devices and the like.

### Introduction and Context

Many semiconductor processing operations use reactants and other gases that can be corrosive to various interior surfaces of the reaction chamber in which the processing operations are performed. These processing operations include depositing material onto substrates, etching material from substrates, and performing cleaning operations of the reaction chamber after depositing and/or etching operations. A reaction chamber of a semiconductor processing tool has interior surfaces that may be comprised of a material, such as a metal or a metal alloy, that is capable of being etched, or corroded, by the reactants or other gases used in these processing operations. The interior surfaces of the reaction chamber that can be corroded, or etched, by the reactants and other gases include the interior reaction chamber walls, e.g., the sidewalls, bottom, and top of the reaction chamber, the showerhead or other gas dispersion apparatuses, and the substrate support, e.g., a pedestal or electrostatic chuck. For example, the reaction chamber interior surfaces may comprise aluminum or an aluminum alloy and the processing operations may use a gas that includes an iodine, a halide, or a chloride, that is capable of etching this aluminum.

Etching or corrosion of the reaction chamber interior surfaces can damage the reaction chamber and lead to wafer defects. For instance, the etched reaction chamber material can be redeposited onto wafers in the reaction chamber which can cause wafer defects. Damage to the reaction chamber may require repair or replacement of the damaged parts, including the reaction chamber itself, which requires additional costs and downtime of the tool. Damage to the surfaces of the reaction chamber, the pedestal, and the pedestal may also adversely affect the performance of these features during processing, such as changing the gas flow of the showerhead or changing the conductivity of the pedestal during plasma generation, which in turn may adversely affect the processing operations and cause wafer defects. Some conventional processing tools have chambers and interior aspects of the chambers, e.g., the showerhead and pedestal, that are made of materials that can withstand the processing gases and chemicals, but these materials are generally very expensive and can increase cost of ownership of the tool. As described below, less costly materials may be used, but these materials are generally more susceptible to corrosion and etching by the processing gases. Additionally, some semiconductor processing is moving to higher temperatures within the chamber and corrosion increases exponentially as the temperature increases. It is therefore desirable to protect against the unwanted corrosion, or etching, of the interior surfaces of the reaction chamber.

### Example Techniques and Apparatuses

Provided herein are various techniques and apparatuses for protecting against and recovering from unwanted etching of interior surfaces of a reaction chamber. In some embodiments, a protective coating may be deposited onto the reaction chamber's interior surfaces, and when exposed to the same process gas, this protective coating is etched at a lower etch rate than the interior surfaces are etched. For example, a deposition operation may use a process gas that contains a halide, and this halide may etch the protective coating at a slower etch rate, such as 20:1, than it etches the material of the interior surfaces. Because the materials and processing conditions (e.g., temperature, pressure) used in the numerous processing operations may vary, yet may still cause unwanted etching of the reaction chamber interior surfaces, in some embodiments the composition of this protective coating may be specifically tailored to the corrosive gas(es) and/or the processing conditions used in the processing operation such that the protective coating is etched by that process gas at a lower etch rate than the interior surfaces are etched by that same process gas. The phrases “protective coating”, “protective material”, and “layer of protective material” are used herein interchangeably and are intended to have the same meaning.

In some embodiments, more than one deposition of the protective coating may occur in order to further protect against, and recover from, unwanted etching of the reaction chamber's interior surfaces. For example, the present inventors discovered that in some instances, after the protective coating is deposited onto the reaction chamber's interior surfaces, subsequent processing etched through that protective coating and etched some of the reaction chamber's interior surfaces. By performing one or more additional depositions of the protective coating onto the reaction chamber's interior surfaces, the present inventors discovered that the etching of the reaction chamber's interior in later processing operations was prevented and stopped. This may be considered a recovery from the etching—when etching of the reaction chamber's interior surfaces that has occurred is subsequently stopped by depositing one or more additional layers of the protective material in the reaction chamber. In some embodiments, etching or corrosion of the reaction chamber's material may be indicated by the presence of this material within the interior volume of reaction chamber and/or on the wafer. If it is determined that an amount of measured reaction chamber material rises above a particular threshold within the reaction chamber or on a wafer, then this may indicate the reaction chamber is being etched and the protective coating may be applied in response to this determination. In some instances, multiple depositions of the protective material may occur during the processing of a single batch of substrates. A protective coating may also be applied before each batch of substrates is processed and after a cleaning operation performed in between two batches.

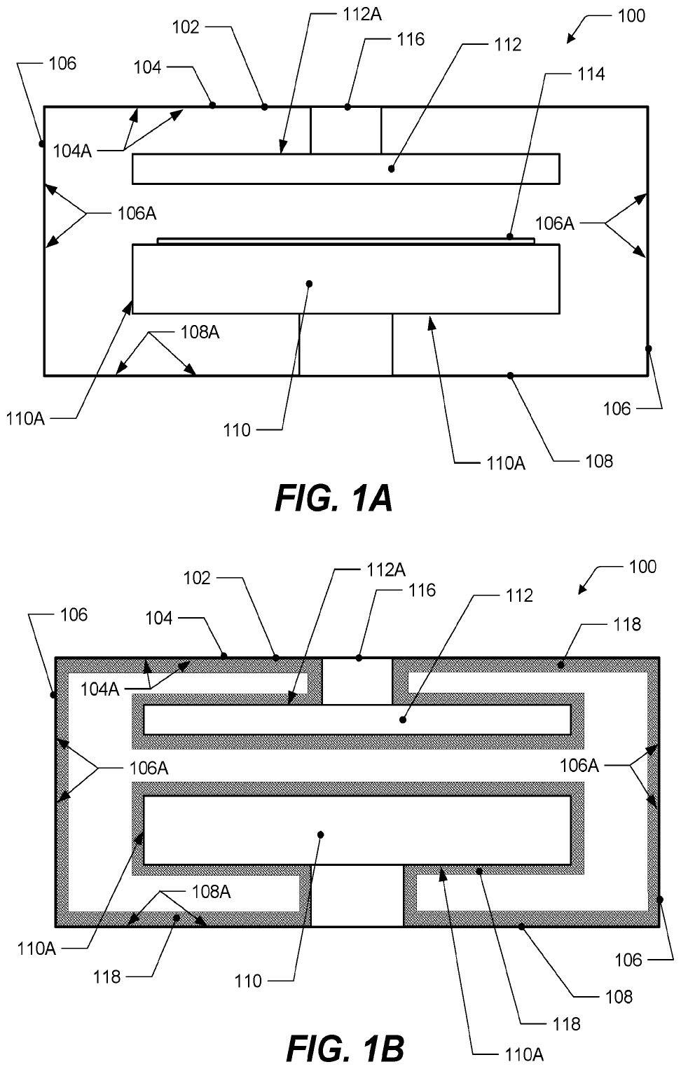

FIG. 1A depicts a simplified exemplary view of a reaction chamber in which processes in accordance with the present disclosure may be implemented. A reaction chamber 100 includes chamber exterior walls 102. Positioned within the processing chamber 100 is a substrate support 110 (e.g., pedestal or electrostatic chuck), on which the substrate 114, e.g., a partially-fabricated semiconductor wafer, is held for processing. The processing chamber also includes a showerhead 112, and one or more inlets 116 for process gases and/or plasma. In some embodiments, a direct and/or remote plasma source (not shown) is provided in or upstream of the processing chamber. The plasma sources include plasma generator components (e.g., coils, electrodes, etc.) for producing a plasma, which may be an inductively coupled plasma (ICP), a capacitively coupled plasma (CCP), or a microwave generated plasma, etc.

As used herein, the reaction chamber's interior surfaces include the surfaces of the reaction chamber walls and the surfaces of the elements and structures within the reaction chamber. As illustrated in FIG. 1A, the reaction chamber includes side walls 106 with side wall surfaces 106A, atop 104 with a top surface 104A, and a bottom 108 with a bottom surface 108A, which are considered at least some of the reaction chamber's 100 interior surfaces. The exposed surfaces of the showerhead 112 and the pedestal 110, i.e., surfaces 112A and 110A, respectively, are also considered the reaction chamber's 100 interior surfaces. The reaction chamber's side walls 106, top 104, and bottom 108, the substrate support 110, and the showerhead 112 may be made of a metal or metal alloy that forms the exterior surface, as well as an exterior region, of each of these elements. In some embodiments, the metal may be aluminum or an aluminum alloy. In some embodiments, the reaction chamber's side walls 106, top 104, and bottom 108, the substrate support 110, and the showerhead 112 may be made of a ceramic material or include a ceramic material. In some embodiments, the material of the interior surfaces is considered the material of which the structures are made, and not coatings or other layers applied to these structures. For example, in some instances the pedestal 110 structure may be made of a material that comprises aluminum and it is the exterior surface 110A of this aluminum that is considered an internal surface of the reaction chamber 100.

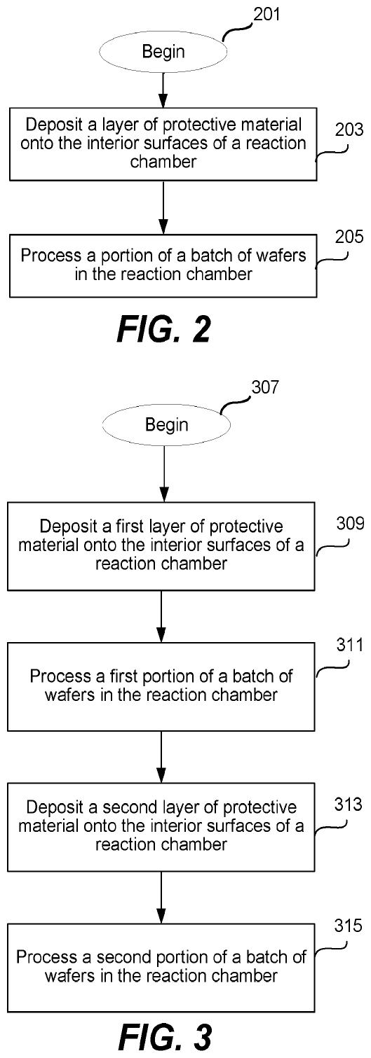

Various techniques described herein may be used to protect these interior surfaces from damage and to recover from any such damage. FIG. 2 depicts an example technique in accordance with the present disclosure. In operation 201, the process begins and in operation 203, a layer of protective material is deposited onto the interior surfaces of the reaction chamber. During this deposition, no wafers are positioned in the reaction chambers; this deposition is not the deposition of material onto wafers. FIG. 1B depicts the reaction chamber of FIG. 1A with a layer of protective material deposited on the interior surfaces of the reaction chamber. As can be seen, the layer of protective material 118, shown with shading, has been deposited onto the top surface 104A, the side wall surface 106A, the bottom surface 108A, the showerhead's exterior surface 112A, and the substrate support's exterior surface 110A. As described in more detail below, this protective material 118 protects the reaction chamber's interior surfaces from damage by gases used and byproducts produced during processing operations.

In some embodiments, the deposition of the protective material may be performed using atomic layer deposition (ALD). This ALD deposition is performed on all of the features of the reaction chamber upon which the protective layer is to be applied, including on the showerhead, substrate support, and chamber walls. In some embodiments, the ALD deposition is performed on all these reaction chamber features at the same time.

ALD is a film forming technique which is well-suited to the deposition of conformal films due to the fact that a single cycle of ALD only deposits a single thin layer of material, the thickness being limited by the amount of one or more film precursor reactants which may adsorb onto the substrate surface (i.e., forming an adsorption-limited layer) prior to the film-forming chemical reaction itself. Multiple “ALD cycles” may then be used to build up a film of the desired thickness, and since each layer is thin and conformal, the resulting film substantially conforms to the shape of the underlying devices structure. In certain embodiments, each ALD cycle includes the following steps: (1) Exposure of the substrate surface to a first precursor, (2) Purge of the reaction chamber in which the substrate is located, (3) Activation of a reaction of the substrate surface, typically with a plasma and/or a second precursor, and (4) Purge of the reaction chamber in which the substrate is located. The duration of each ALD cycle is typically less than 25 seconds or less than 10 seconds. The plasma exposure step (or steps) of the ALD cycle may be of a short duration, such as a duration of 1 second or less.

As used herein, a “layer” or protective material may be the overall thickness of a deposited layer that is made up of multiple layers of material. For instance, a layer of protective material may be the total thickness of this layer that was achieved by depositing 100 individual layers of material.

In operation 205, a portion of a batch of wafers may be processed in the reaction chamber. Under typical circumstances, a collection of wafers, e.g. one or more, such as one, two, or four wafers, are processed at a time in a processing chamber, e.g., a deposition is performed on the wafers within the processing chamber. For example, in a multi-station tool such as are available from Lam Research Corporation, four wafers may enter into processing chamber, be processed, and then removed. Next, four additional unprocessed wafers may be delivered into the processing chamber for processing. Such transport and processing of collections of wafers until a total target quantity or “batch” between required chamber cleans is reached may be referred to as “batch processing.” Wafers may be serially processed, one or more at a time as described above, until a maximum reaction chamber batch size, for example determined by a maximum allowable total deposition accumulation limit or wafer count correlated with such, is reached. Accordingly, in some embodiments, each batch includes a plurality of substrates that may have anywhere from a few substrates to several hundred substrates.

A “batch” of wafers refers to the total number of wafers that can be processed in the reaction chamber between reaction chamber clean cycles, before the reactor needs to be shut down for full cleaning in order to continue processing wafers without risk of process drift and/or wafer contamination from particle generation such as flaking of accumulated off-target material deposition on internal reactor components, particularly sidewalls, due to processing of the wafers within the reaction chamber. Accordingly, a “batch” of wafers refers the number of substrates that may be processed for a particular ALD process before or when the accumulation limit is reached. For example, an ALD process in a particular chamber may have an accumulation limit of 20,000 Å which is the point at which the accumulation on the chamber causes adverse effects on substrates processed in that chamber, i.e., the accumulation limit, and a batch of substrates processed in that chamber is limited to the number of substrates that may be processed before the accumulation limit of 20,000 Å is reached. In certain embodiments, the first wafer in a batch is the first wafer processed after a chamber clean. In multi-station reactors, multiple wafers are processed together, so the first wafer may be part of a group of wafers that are collectively the first wafers processed in a batch. The last wafer is the last wafer processed before a chamber clean. In multi-station reactors there will be multiple last wafers.

In operation 205 of FIG. 2, the portion of the batch of wafers refers to a number of wafers smaller than the whole batch of wafers are processed. For instance, the batch may include 500 wafers and the portion of the batch may be 100 wafers. The processing of the portion of the batch of wafers includes various semiconductor processing operations, such as etching and deposition. The processing operations performed on the portion of the batch of wafers may use gases, chemicals, reactants, and the like that can damage the interior surfaces of the reaction chamber; in some instances, the byproducts during these operations may also damage the interior surfaces. This damage includes corrosion, which is inclusive of etching, of the exterior surfaces and underlying material by removing such material. These semiconductor processing operations include etching operations, depositing operations, and cleaning operations performed after etching and depositing.

In some embodiments, the gases used in etching operations may corrode the interior surfaces of the reaction chamber. These gases and reactants may include halides, iodines, and chlorides. Some specific, non-limiting examples include nitrogen tri-fluoride (NF₃), tetra-fluoro-methane (CF₄), tetrafluoroethylene (C₂F₄), hexafluoroethane (C₂F₆), and octafluoropropane (C₃F₈), tri-fluoro-methane (CHF₃), sulfur hexafluoride (SF₆), and molecular fluorine (F₂), thynlchloride (SOCl₂), phosphoryl chloride (POCl₃), sulfurdioxide (SO₂), and dichlorodiethyl sulfide (C₄H₈Cl₂S). In some embodiments, a combination of nitrogen-containing gases and fluorine-containing gases may be used, such as a mixture of nitrogen/fluorine (N₂/F₂). Additionally, processing byproducts may also damage and corrode the reaction chamber's interior surfaces, such as a hydrogen sulfide byproduct. In some embodiments, the gases used in deposition operations may corrode the interior surfaces of the reaction chamber. For example, these gases may be the precursors used in atomic layer deposition, such as hafnium tetrachloride (HfCl₄), titanium tetrachloride (TiCl₄), and hydrogen sulfide (H₂S). Similarly, in some embodiments, the gases used in reaction chamber cleaning operations may corrode and etch the interior surfaces of the reaction chamber. For example, these gases may be thynlchloride (SOCl₂).

As mentioned herein, in some embodiments, the reaction chamber's interior surfaces may be made of a material that is susceptible, or more susceptible than other materials, to damage (e.g., corrosion and etching) by the above-referenced gases. Materials that are less susceptible to damage may be more expensive than the materials that are more susceptible; it is desirable to use these less susceptible materials to save costs which is achievable using the techniques and apparatuses herein. For example, the material may be an aluminum or an aluminum alloy that is susceptible to damage by hydrogen sulfide, iodine compounds, halide compounds, and chloride compounds. In one example, the process gas chlorine etches aluminum more than titanium under the same process conditions. Aluminum is generally cheaper than titanium and the techniques provided herein allow the use of aluminum for the reaction chamber and corresponding parts in the reaction chamber, such as the showerhead and pedestal. Additionally, aluminum may be cheaper than ceramic material and thus may replace this ceramic material.

The layer of protective material is designed to protect the reaction chamber's interior surfaces by, in some instances, degrading (i.e., corroding or etching) slower than the material of the reaction chamber's interior surfaces. This difference in etch rates, or corrosion rates, between the protective coating and the material of the reaction chamber's interior surfaces is considered “selectivity” of the protective material; the higher the selectivity, the slower the protective material is etched, or corroded, as the material of the reaction chamber's interior surfaces under the same conditions. In some embodiments, it is desirable to have a high selectivity of the protective material such that it corrodes or is etched at a slower rate than the material of the reaction chamber's interior surfaces under the same processing conditions. In some instances, it is desirable and advantageous to have the selectivity, or difference in etch rates, be at least 20 to 1 and at least 100 to 1. In some such instances, this may enable 20 or 100 wafers to be processed before the protective material is corroded or etched through and the material of the reaction chamber's interior surfaces begins being corroded or etched. For example, under a first set of process conditions, the material of the reaction chamber's interior surfaces may be an aluminum alloy and the protective material may be silicon oxide, and under the same set of process conditions, the aluminum alloy is etched by a process gas at a rate 20 or 100 times greater than the silicon oxide.

As state herein, the protective material may comprise “silicon oxide” which is referred to herein as including chemical compounds including silicon and oxygen atoms, including any and all stoichiometric possibilities for SiₓO_{y}, including integer values of x and y and non-integer values of x and y. For example, “silicon oxide” includes compounds having the formula SiOₙ, where 1≤n≤2, where n can be an integer or non-integer values. “Silicon oxide” can include sub-stoichiometric compounds such as SiO_{1.8}. “Silicon oxide” also includes silicon dioxide (SiO₂) and silicon monoxide (SiO). “Silicon oxide” also includes both natural and synthetic variations and also includes any and all crystalline and molecular structures, including tetrahedral coordination of oxygen atoms surrounding a central silicon atom. “Silicon oxide” also includes amorphous silicon oxide and silicates.

Referring back to operation 203, the parameters and characteristics of the deposited protective material may differ according to various factors, such as the processing conditions and processing operations. For instance, corrosion and etch rates of material can increase as temperature increases. Thus, in some instances the etch rates of the protective material will increase as the temperatures of processing operations also increase, thus requiring a thicker protective material or a different protective material, or both. Additionally, different process gases may cause different etch rates of the same material. The present inventors have found that for some embodiments, it is advantageous to have a protective material with a thickness of between 1,000 Å and 30,000 Å, such as 2,000 Å, 2,500 Å, 3,000 Å, 4,000 Å, 4,500 Å, 5,000 Å, 5,500 Å, and 6,000 Å, 7,000 Å, 8,000 Å, 10,000 Å, 15,000 Å, 20,000 Å, and 25,000 Å, for example. Furthermore, the present inventors found that it is advantageous to use, for some processing conditions, a protective material containing silicon oxide (e.g., SiO₂), including when the material of the reaction chamber's interior surfaces is made of an aluminum, such as an aluminum alloy.

In some embodiments, after an initial deposition of the protective material, additional depositions of the protective material may occur during or after processing a batch of substrates. These additional depositions may replenish corroded or etched away protective material in order to continue protecting the interior surfaces of the reaction chamber. In some embodiments, the protective material may corrode, i.e., or be etched, during the processing of a single batch of wafers such that the interior surfaces of the reaction chamber are corroded or etched during the processing of this single batch. The occurrence of this may be calculated using the known parameters of the processing conditions, including the etch rate of the protective material, to determine when, after a number of wafers or cycles of deposition for instance, the protective material has been etched away from one or more locations and the interior surfaces of the reaction chamber are exposed and etched. The etch rate may be determined in some instances by depositing a film onto a wafer and then etching using the known etch chemistry to etch and then measure how much deposited film is remaining, which gives the etch rate. Accordingly, in some embodiments, the protective material may be redeposited on the interior surfaces of the reaction chamber one or more times during the processing of a batch of substrates. This may include at periodic intervals, such as every N wafers in the batch or after Y etching minutes.

FIG. 3 depicts another example technique in accordance with the present disclosure. In operation 307 the process begins, in operation 309 a layer of protective material is deposited onto the interior surfaces of the reaction chamber as described above, e.g., operation 203 in FIG. 2, and in operation 311 a first portion of a batch of wafers is processed as described above, e.g., operation 205 in FIG. 2. In FIG. 3, after operation 311 is performed, operation 313 deposits a second layer of protective material onto the interior surfaces of the reaction chamber, followed by the processing of a second portion of the batch of wafers in operation 315. This sequence thus performs an initial and subsequent protective material depositions before the batch of substrates is completed and the chamber is cleaned. In some instances, operations 313 and 315 may be repeated until the batch of wafers is completed processing. In some embodiments, operations 313 and 315 may be repeated after different numbers of wafers are processed in the reaction chamber because, for instance, the processing conditions within the reaction chamber may change such that the protective material is etched or corroded differently (e.g., more or less) over the course of processing the batch of wafers.

In some instances, etching or corrosion of the interior surfaces of the reaction chamber may be evidenced by the presence of the material of the interior surfaces of the reaction chamber within the chamber's internal volume and/or on processed wafers. Accordingly, some embodiments detect and measure the presence of the material of the interior surfaces of the reaction chamber and based on this detection and measurement, perform a subsequent protective material deposition. The presence of the material of the interior surfaces of the reaction chamber may be measured and detected in various manners, such as measuring the presence of the material of the interior surfaces of the reaction chamber within the chamber's internal volume and/or on processed wafers. For example, a residual gas analyzer or a spectroscope are able to detect and measure an amount of material within the reaction chamber. This includes detecting and measuring the amount of the material of the reaction chamber's interior surfaces, such as an aluminum or aluminum alloy. In some embodiments, this may be an in-situ measurement and detection, such as during a processing operation or during the processing of the batch of wafers. In another example, the wafers themselves may be examined for the presence of the material of the reaction chamber's interior surfaces on the wafer surface. For instance, this may include performing Scanning Transmission Electron Microscopy (STEM) or Transmission Electron Microscopy (TEM) imaging to visually see remaining film, ellipsometry to measure optically, X-ray photoelectron spectroscopy (XPS), and electron energy loss spectroscopy (EELS) to chemically look at what is on the wafer to detect and measure the amounts of the wafer elements, such as the presence of the material of the reaction chamber's interior surfaces (e.g., aluminum) on the wafer surface.

A subsequent protective material deposition may be performed in response to one or more of the detection of the material of the reaction chamber's interior surfaces within the reaction chamber's interior volume, the detection of the material of the reaction chamber's interior surfaces on the wafer's surface, the determination that the quantity of this material within the chamber is above a threshold, and the determination that the quantity of this material on a wafer is above another threshold. This subsequent protective material deposition may occur during the batch of substrates (similar to FIG. 3), while in some other embodiments it may occur between processing batches of wafers in the same chamber.

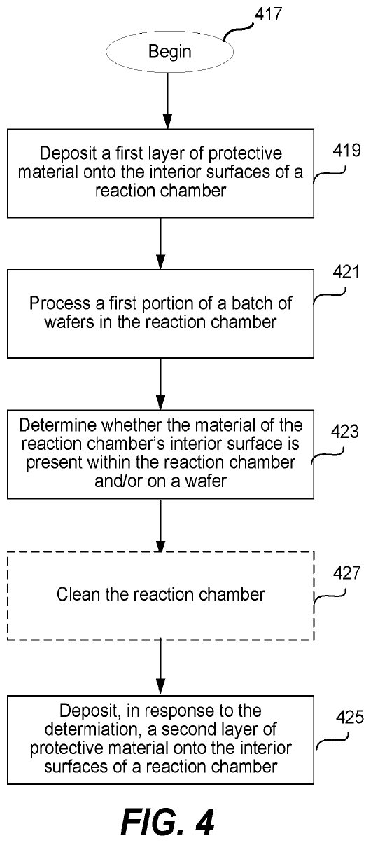

FIG. 4 depicts yet another example technique in accordance with the present disclosure. In operation 417 the process begins, in operation 419 a layer of protective material is deposited onto the interior surfaces of the reaction chamber as described above, e.g., operation 203 in FIG. 2, and in operation 421 a first portion of a batch of wafers is processed as described above, e.g., operation 205 in FIG. 2. In operation 423, one or more of the above-described determinations is made, including whether the material of the reaction chamber's interior surfaces is present within the reaction chamber's interior volume, is present on a wafer, is present within the reaction chamber's interior volume above a first threshold, and/or is present on a wafer above a second threshold. One or more of these determinations may be made, such as determining that both the material of the reaction chamber's interior surfaces is present within the chamber interior volume and on the wafer. In other embodiments, only one of these determinations may be made, such as whether the material of the reaction chamber's interior surfaces is present above a particular threshold on the wafer. In response to one or more of these determinations, operation 425 deposits a second layer of protective material onto the interior surfaces of the reaction chamber. Similar to above, this deposition of the second protective layer is performed while no substrates are in the reaction chamber. This second, subsequent deposition of the protective material may thus cause the recovery of the protective material such that it continues to protect the interior surfaces of the reaction chamber from corrosion and etching.

Similar to above, in some embodiments, the determination of operation 423 may be made during the processing of the batch of substrates, and the deposition of operation 425 may also be performed during the processing of the batch of substrates, i.e., before the batch of substrates is completed.

In some embodiments, the determination of operation 423 may be made during or after the processing of the batch of substrates, while the deposition of operation 425 may be performed after the batch of substrates is completed processing in the reaction chamber. This may allow an optional cleaning operation, optional operation 427 in FIG. 4, to be performed after operation 421 and before operation 425 so that accumulation and other unwanted byproducts can be removed from the reaction chamber and allow the second layer of protective material to be deposited directly on the first layer of protective material and any exposed surfaces of the reaction chamber's interior surfaces. Accordingly, this deposition of operation 425 may include depositing the second layer of protective material onto the first layer of material and onto the plurality of interior surfaces of the reaction chamber. In some such embodiments, the thickness of the second layer of protective material may be less than or equal to thickness of the first layer of protective material. In some instances, depositing the same thickness of protective material as the first layer of protective material may provide the original amount of thickness protection to the exposed portions, as well as additional material and protection to the rest of the first layer of protective material. This first layer of protective material may be reduced in thickness after processing the batch of substrates and cleaning the reaction chamber.

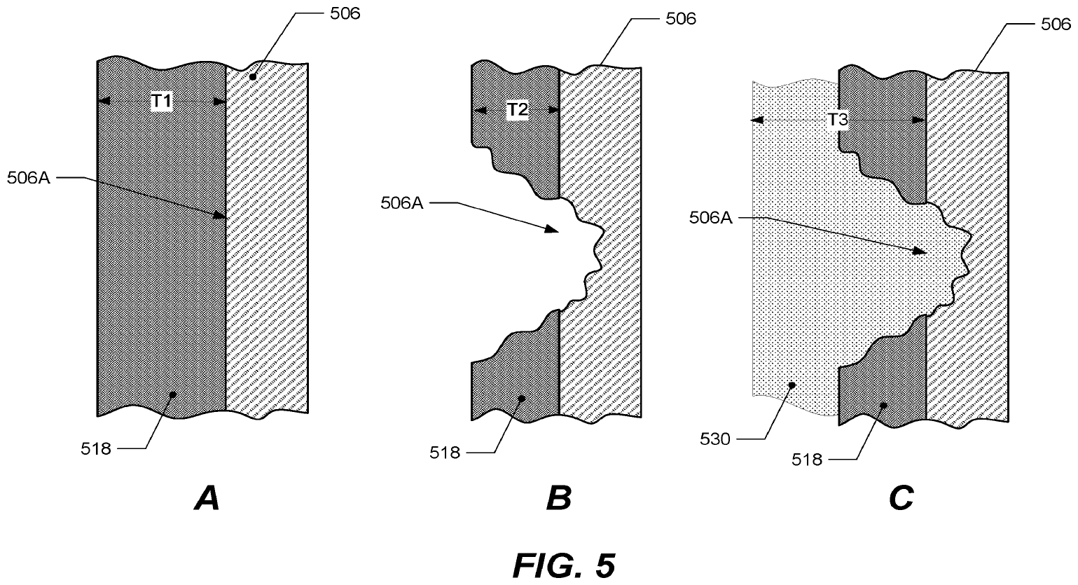

FIG. 5 depicts a graphical representation of depositions of protective material on an interior reaction chamber surface. In panel A of FIG. 5, the protective material 518 is seen deposited onto an interior surface 506A of the reaction chamber, e.g., the side wall 506, such that the protective material 518 has a thickness T1 and covers interior surface 506A. Panel B represents the protective material 518 and the interior surface 506A after some processing operations, e.g., deposition or etching, has etched or corroded the protective material 518 and exposed a section of the interior surface 506A and corroded or etched some of the side wall 506. The presence of this etched away side wall 506 may have been detected as described above. The thickness of the first protective layer has also been reduced to T2 because of the processing operations. Panel C represents the deposition of a second layer of protective material 530 onto the first protective material and the exposed surface of the side wall 506. As can be seen, this second layer of protective material 530 has covered the exposed portion of the side wall 506 and the first layer of material 518 thereby causing the recovery of this exposed portion of the reaction chamber and providing additional protection to the reaction chamber internal surfaces. For instance, the overall thickness T3 of both the first and second layers of protective material 518 and 530 may be greater than the thickness T1 of the originally deposited first layer of protective material.

### Deposition Processing Examples

Some semiconductor processes are used to deposit one or more layers of a material onto a substrate. Example deposition processes include chemical vapor deposition (“CVD”), plasma-enhanced CVD (“PECVD”), atomic layer deposition (“ALD”), low pressure CVD, ultra-high CVD, physical vapor deposition (“PVD”), and conformal film deposition (“CFD”). Some CVD processes may deposit a film on a wafer surface by flowing one or more gas reactants into a reactor which form film precursors and by-products. The precursors are transported to the wafer surface where they are adsorbed by the wafer, diffused into the wafer, and deposited on the wafer by chemical reactions, including by the generation of a plasma in PECVD. Some other deposition processes involve multiple film deposition cycles, each producing a “discrete” film thickness. ALD is one such film deposition method, but any technique which puts down thin layers of film and used in a repeating sequential matter may be viewed as involving multiple cycles of deposition.

As discussed above, as devices sizes continue to shrink and ICs move to employing 3-D transistors and other 3-D structures, the ability to deposit a precise amount (thickness) of conformal film material—dielectrics in particular, but also various dopant-containing materials—has become increasingly important. Atomic layer deposition is one technique for accomplishing conformal film deposition that typically involves multiple cycles of deposition in order to achieve a desired thickness of film.

In contrast with CVD process, where activated gas phase reactions are used to deposit films, ALD processes use surface-mediated deposition reactions to deposit films on a layer-by-layer basis. For instance, in one class of ALD processes, a first film precursor (P1) is introduced in a processing chamber in the gas phase, is exposed to a substrate, and is allowed to adsorb onto the surface of the substrate (typically at a population of surface active sites). Some molecules of P1 may form a condensed phase atop the substrate surface, including chemisorbed species and physisorbed molecules of P1. The volume surrounding the substrate surface is then evacuated to remove gas phase and physisorbed P1 so that only chemisorbed species remain. A second film precursor (P2) may then be introduced into the processing chamber so that some molecules of P2 adsorb to the substrate surface. The volume surrounding the substrate within the processing chamber may again be evacuated, this time to remove unbound P2. Subsequently, energy provided to the substrate (e.g., thermal or plasma energy) activates surface reactions between the adsorbed molecules of P1 and P2, forming a film layer. Finally, the volume surrounding the substrate is again evacuated to remove unreacted P1 and/or P2 and/or reaction by-product, if present, ending a single cycle of ALD.

ALD techniques for depositing conformal films having a variety of chemistries—and also many variations on the basic ALD process sequence—are described in detail in U.S. patent application Ser. No. 13/084,399, filed Apr. 11, 2011, titled “PLASMA ACTIVATED CONFORMAL FILM DEPOSITION” (Attorney Docket No. NOVLP405), U.S. patent application Ser. No. 13/242,084, filed Sep. 23, 2011, titled “PLASMA ACTIVATED CONFORMAL DIELECTRIC FILM DEPOSITION,” now U.S. Pat. No. 8,637,411 (Attorney Docket No. NOVLP427), U.S. patent application Ser. No. 13/224,240, filed Sep. 1, 2011, titled “PLASMA ACTIVATED CONFORMAL DIELECTRIC FILM DEPOSITION” (Attorney Docket No. NOVLP428), and U.S. patent application Ser. No. 13/607,386, filed Sep. 7, 2012, titled “CONFORMAL DOPING VIA PLASMA ACTIVATED ATOMIC LAYER DEPOSITION AND CONFORMAL FILM DEPOSITION” (Attorney Docket No. NOVLP488), each of which is incorporated by reference herein in its entirety for all purposes. As described in these prior applications, a basic ALD cycle for depositing a single layer of material on a substrate may include: (i) adsorbing a film precursor onto a substrate at a process station such that it forms an adsorption-limited layer, (ii) removing, when present, unadsorbed precursor (“unadsorbed precursor” defined to include desorbed precursor) from the vicinity of the process station, (iii) reacting the adsorbed-precursor to form a layer of film on the substrate, and optionally (iv) removing desorbed film precursor and/or reaction by-product from the vicinity of the process station. The removing in operations (ii) and (iv) may be done via purging, evacuating, pumping down to a base pressure (“pump-to-base”), etc. the volume surrounding the substrate. In some embodiments, the purge gas may be the same as the main plasma feed gas. The foregoing sequence of operations (i) through (iv) represent a single ALD cycle resulting in the formation of a single layer of film. However, since a single layer of film formed via ALD is typically very thin—often it is only a single molecule thick—multiple ALD cycles are repeated in sequence to build up a film of appreciable thickness. Thus, if it is desired that a film of say N layers be deposited (or, equivalently, one might say N layers of film), then multiple ALD cycles (operations (i) through (iv)) may be repeated in sequence N times.

It is noted that this basic ALD sequence of operations (i) through (iv) doesn't necessary involve two chemiadsorbed reactive species P1 and P2 as in the example described above, nor does it even necessarily involve a second reactive species, although these possibilities/options may be employed, depending on the desired deposition chemistries involved.

Due to the adsorption-limited nature of ALD, however, a single cycle of ALD only deposits a thin film of material, and oftentimes only a single monolayer of material. For example, depending on the exposure time of the film precursor dosing operations and the sticking coefficients of the film precursors (to the substrate surface), each ALD cycle may deposit a film layer only about 0.5 to 3 Angstroms thick. Thus, the sequence of operations in a typical ALD cycle—operations (i) through (iv) just described—are generally repeated multiple times in order to form a conformal film of the desired thickness. Thus, in some embodiments, operations (i) through (iv) are repeated consecutively at least 1 time, or at least 2 times, or at least 3 times, or at least 5 times, or at least 7 times, or at least 10 times in a row. An ALD film may be deposited at a rate of about or between 0.1 Å and 2.5 Å per ALD cycle, or about or between 0.2 Å and 2.0 Å per ALD cycle, or about or between 0.3 Å and 1.8 Å per ALD cycle, or about or between 0.5 Å and 1.5 Å per ALD cycle, or about or between 0.1 Å and 1.5 Å per ALD cycle, or about or between 0.2 Å and 1.0 Å per ALD cycle, or about or between 0.3 Å and 1.0 Å per ALD cycle, or about or between 0.5 Å and 1.0 Å per ALD cycle.

In some film forming chemistries, an auxiliary reactant or co-reactant—in addition to what is referred to as the “film precursor”—may also be employed. In certain such embodiments, the auxiliary reactant or co-reactant may be flowed continuously during a subset of steps (i) through (iv) or throughout each of steps (i) through (iv) as they are repeated. In some embodiments, this other reactive chemical species (auxiliary reactant, co-reactant, etc.) may be adsorbed onto the substrate surface with the film precursor prior to its reaction with the film precursor (as in the example involving precursors P1 and P2 described above), however, in other embodiments, it may react with the adsorbed film precursor as it contacts it without prior adsorption onto the surface of the substrate, per se. Also, in some embodiments, operation (iii) of reacting the adsorbed film precursor may involve contacting the adsorbed film precursor with a plasma. The plasma may provide energy to drive the film-forming reaction on the substrate surface. In certain such embodiments, the plasma may be an oxidative plasma generated in the reaction chamber with application of suitable RF power (although in some embodiments, it may be generated remotely). In other embodiments, instead of an oxidative plasma, an inert plasma may be used. The oxidizing plasma may be formed from one or more oxidants such as O₂, N₂O, or CO₂, and may optionally include one or more diluents such as Ar, N₂, or He. In one embodiment, the oxidizing plasma is formed from O₂ and Ar. A suitable inert plasma may be formed from one or more inert gases such as He or Ar. Further variations on ALD processes are described in detail in the prior patent applications just cited (and which are incorporated by reference).

In some embodiments, a multi-layer deposited film may include regions/portions of alternating composition formed, for example, by conformally depositing multiple layers sequentially having one composition, and then conformally depositing multiple layers sequentially having another composition, and then potentially repeating and alternating these two sequences. Some of these aspects of deposited ALD films are described, for example, in U.S. patent application Ser. No. 13/607,386, filed Sep. 7, 2012, and titled “CONFORMAL DOPING VIA PLASMA ACTIVATED ATOMIC LAYER DEPOSITION AND CONFORMAL FILM DEPOSITION” (Attorney Docket No. NOVLP488); which is incorporated by reference herein in its entirety for all purposes. Further examples of conformal films having portions of alternating composition—including films used for doping an underlying target IC structure or substrate region—as well as methods of forming these films, are described in detail in: U.S. patent application Ser. No. 13/084,399, filed Apr. 11, 2011, and titled “PLASMA ACTIVATED CONFORMAL FILM DEPOSITION” (Attorney Docket No. NOVLP405); U.S. patent application Ser. No. 13/242,084, filed Sep. 23, 2011, and titled “PLASMA ACTIVATED CONFORMAL DIELECTRIC FILM DEPOSITION,” now U.S. Pat. No. 8,637,411 (Attorney Docket No. NOVLP427); U.S. patent application Ser. No. 13/224,240, filed Sep. 1, 2011, and titled “PLASMA ACTIVATED CONFORMAL DIELECTRIC FILM DEPOSITION” (Attorney Docket No. NOVLP428); U.S. patent application Ser. No. 13/607,386, filed Sep. 7, 2012, and titled “CONFORMAL DOPING VIA PLASMA ACTIVATED ATOMIC LAYER DEPOSITION AND CONFORMAL FILM DEPOSITION” (Attorney Docket No. NOVLP488); and U.S. patent application Ser. No. 14/194,549, filed Feb. 28, 2014, and titled “CAPPED ALD FILMS FOR DOPING FIN-SHAPED CHANNEL REGIONS OF 3-D IC TRANSISTORS”; each of which is incorporated by reference herein in its entirety for all purposes.

As detailed in the above referenced specifications, ALD processes are oftentimes used to deposit conformal silicon oxide films (SiOx), however ALD processes may also be used to deposit conformal dielectric films of other chemistries as also disclosed in the foregoing incorporated specifications. ALD-formed dielectric films may, in some embodiments, contain a silicon carbide (SiC) material, a silicon nitride (SiN) material, a silicon carbonitride (SiCN) material, or a combination thereof. Silicon-carbon-oxides and silicon-carbon-oxynitrides, and silicon-carbon-nitrides may also be formed in some embodiment ALD-formed films. Methods, techniques, and operations for depositing these types of films are described in detail in U.S. patent application Ser. No. 13/494,836, filed Jun. 12, 2012, titled “REMOTE PLASMA BASED DEPOSITION OF SiOC CLASS OF FILMS,” Attorney Docket No. NOVLP466/NVLS003722; U.S. patent application Ser. No. 13/907,699, filed May 31, 2013, titled “METHOD TO OBTAIN SiC CLASS OF FILMS OF DESIRED COMPOSITION AND FILM PROPERTIES,” Attorney Docket No. LAMRP046/3149; U.S. patent application Ser. No. 14/062,648, titled “GROUND STATE HYDROGEN RADICAL SOURCES FOR CHEMICAL VAPOR DEPOSITION OF SILICON-CARBON-CONTAINING FILMS”; and U.S. patent application Ser. No. 14/194,549, filed Feb. 28, 2014, and titled “CAPPED ALD FILMS FOR DOPING FIN-SHAPED CHANNEL REGIONS OF 3-D IC TRANSISTORS”; each of which is hereby incorporated by reference in its entirety and for all purposes.

Other examples of film deposition via ALD include chemistries for depositing dopant-containing films as described in the patent applications listed and incorporated by reference above (U.S. patent application Ser. Nos. 13/084,399, 13/242,084, 13/224,240, and 14/194,549). As described therein, various dopant-containing film precursors may be used for forming the dopant-containing films, such as films of boron-doped silicate glass (BSG), phosphorous-doped silicate glass (PSG), boron phosphorus doped silicate glass (BPSG), arsenic (As) doped silicate glass (ASG), and the like. The dopant-containing films may include B₂O₃, B₂O, P₂O₅, P₂O₃, As₂O₃, As₂O₅, and the like. Thus, dopant-containing films having dopants other than boron are feasible. Examples include gallium, phosphorous, or arsenic dopants, or other elements appropriate for doping a semiconductor substrate, such as other valence III and V elements.

As for ALD process conditions, ALD processes may be performed at various temperatures. In some embodiments, suitable temperatures within an ALD reaction chamber may range from between about 25° C. and 450° C., or between about 50° C. and 300° C., or between about 20° C. and 400° C., or between about 200° C. and 400° C., or between about 100° C. and 350° C.

Likewise, ALD processes may be performed at various ALD reaction chamber pressures. In some embodiments, suitable pressures within the reaction chamber may range from between about 10 mTorr and 10 Torr, or between about 20 mTorr and 8 Torr, or between about 50 mTorr and 5 Torr, or between about 100 mTorr and 2 Torr.

Various RF power levels may be employed to generate a plasma if used in operation (iii). In some embodiments, suitable RF power may range from between about 100 W and 10 kW, or between about 200 W and 6 kW, or between about 500 W, and 3 kW, or between about 1 kW and 2 kW.

Various film precursor flow rates may be employed in operation (i). In some embodiments, suitable flow rates may range from about or between 0.1 mL/min to 10 mL/min, or about or between 0.5 mL/min and 5 mL/min, or about or between 1 mL/min and 3 mL/min.

Various gas flow rates may be used in the various operations. In some embodiments, general gas flow rates may range from about or between 1 L/min and 20 L/min, or about or between 2 L/min and 10 L/min. For the optional inert purge steps in operations (ii) and (iv), an employed burst flow rate may range from about or between 20 L/min and 100 L/min, or about or between 40 L/min and 60 L/min.

Once again, in some embodiments, a pump-to-base step refers to pumping the reaction chamber to a base pressure by directly exposing it to one or more vacuum pumps. In some embodiments, the base pressure may typically be only a few milliTorr (e.g., between about 1 and 20 mTorr). Furthermore, as indicated above, a pump-to-base step may or may not be accompanied by an inert purge, and thus carrier gases may or may not be flowing when one or more valves open up the conductance path to the vacuum pump.

Also, once again, multiple ALD cycles may be repeated to build up stacks of conformal layers. In some embodiments, each layer may have substantially the same composition whereas in other embodiments, sequentially ALD deposited layers may have differing compositions, or in certain such embodiments, the composition may alternate from layer to layer or there may be a repeating sequence of layers having different compositions, as described above. Thus, depending on the embodiment, certain stack engineering concepts, such as those disclosed in the patent applications listed and incorporated by reference above (U.S. patent application Ser. Nos. 13/084,399, 13/242,084, and 13/224,240) may be used to modulate boron, phosphorus, or arsenic concentration in these films.

Many semiconductor fabrication processes deposit materials using plasma-enhanced chemical vapor deposition (“PECVD”). In a typical PECVD reaction, a substrate is heated to an operating temperature and exposed to one or more volatile precursors which react and/or decompose to produce the desired deposit on the substrate surface. The PECVD process generally begins by flowing one or more reactants into the reaction chamber. The reactant delivery may continue as a plasma is generated which exposes the substrate surface to the plasma, which in turn causes deposition to occur on the substrate surface. This process continues until a desired film thickness is reached, after which the plasma is generally extinguished and the reactant flow is terminated. Next, the reaction chamber may be purged and post-deposition steps may be performed.

The PECVD process may be used to deposit a wide variety of film types and in particular implementations to fill gaps with these film types. Some may be used to form undoped silicon oxides, other film types such as nitrides, carbides, oxynitrides, carbon-doped oxides, nitrogen-doped oxides, borides, etc. may also be formed. Oxides include a wide range of materials including undoped silicate glass (USG), doped silicate glass. Examples of doped glasses included boron doped silicate glass (BSG), phosphorus doped silicate glass (PSG), and boron phosphorus doped silicate glass (BPSG). Still further, the PECVD process may be used for metal deposition and feature fill.

In certain embodiments, the deposited film is a silicon-containing film. In these cases, the silicon-containing reactant may be for example, a silane, a halosilane or an aminosilane. A silane contains hydrogen and/or carbon groups, but does not contain a halogen. Examples of silanes are silane (SiH₄), tetramethylsilane (C₄H₁₂Si; 4MS) disilane (Si₂H₆), and organo silanes such as methylsilane, ethylsilane, isopropylsilane, t-butylsilane, dimethylsilane, diethylsilane, di-t-butylsilane, allylsilane, sec-butylsilane, thexylsilane, isoamylsilane, t-butyldisilane, di-t-butyldisilane, tetra-ethyl-ortho-silicate (also known as tetra-ethoxy-silane or TEOS) and the like. A halosilane contains at least one halogen group and may or may not contain hydrogens and/or carbon groups. Examples of halosilanes are iodosilanes, bromosilanes, chlorosilanes and fluorosilanes. Although halosilanes, particularly fluorosilanes, may form reactive halide species that can etch silicon materials, in certain embodiments described herein, the silicon-containing reactant is not present when a plasma is struck. Specific chlorosilanes are tetrachlorosilane (SiCl₄), trichlorosilane (HSiCl₃), dichlorosilane (H₂SiCl₂), monochlorosilane (ClSiH₃), chloroallylsilane, chloromethylsilane, dichloromethylsilane, chlorodimethylsilane, chloroethylsilane, t-butylchlorosilane, di-t-butylchlorosilane, chloroisopropylsilane, chloro-sec-butylsilane, t-butyldimethylchlorosilane, thexyldimethylchlorosilane, and the like. An aminosilane includes at least one nitrogen atom bonded to a silicon atom, but may also contain hydrogens, oxygens, halogens and carbons. Examples of aminosilanes are mono-, di-, tri- and tetra-aminosilane (H₃Si(NH₂)₄, H₂Si(NH₂)₂, HSi(NH₂)₃ and Si(NH₂)₄, respectively), as well as substituted mono-, di-, tri- and tetra-aminosilanes, for example, t-butylaminosilane, methylaminosilane, tert-butylsilanamine, bis(tertiarybutylamino)silane (SiH₂(NHC(CH₃)₃)₂ (BTBAS), tert-butyl silylcarbamate, SiH(CH₃)—(N(CH₃)₂)₂, SiHCl—(N(CH₃)₂)₂, (Si(CH₃)₂NH)₃ and the like. A further example of an aminosilane is trisilylamine (N(SiH₃)).

In other cases, the deposited film contains metal. Examples of metal-containing films that may be formed include oxides and nitrides of aluminum, titanium, hafnium, tantalum, tungsten, manganese, magnesium, strontium, etc., as well as elemental metal films. Example precursors may include metal alkylamines, metal alkoxides, metal alkylamides, metal halides, metal β-diketonates, metal carbonyls, organometallics, etc. Appropriate metal-containing precursors will include the metal that is desired to be incorporated into the film. For example, a tantalum-containing layer may be deposited by reacting pentakis(dimethylamido)tantalum with ammonia or another reducing agent. Further examples of metal-containing precursors that may be employed include trimethylaluminum, tetraethoxytitanium, tetrakis-dimethylamido titanium, hafnium tetrakis(ethylmethylamide), bis(cyclopentadienyl)manganese, bis(n-propylcyclopentadienyl) magnesium, etc.

In certain implementations, an oxygen-containing oxidizing reactant is used. Examples of oxygen-containing oxidizing reactants include oxygen, ozone, nitrous oxide, carbon monoxide, etc.

In some embodiments, the deposited film contains nitrogen, and a nitrogen-containing reactant is used. A nitrogen-containing reactant contains at least one nitrogen, for example, ammonia, hydrazine, amines (e.g., amines bearing carbon) such as methylamine, dimethylamine, ethylamine, isopropylamine, t-butylamine, di-t-butylamine, cyclopropylamine, sec-butylamine, cyclobutylamine, isoamylamine, 2-methylbutan-2-amine, trimethylamine, diisopropylamine, diethylisopropylamine, di-t-butylhydrazine, as well as aromatic containing amines such as anilines, pyridines, and benzylamines. Amines may be primary, secondary, tertiary or quaternary (for example, tetraalkylammonium compounds). A nitrogen-containing reactant can contain heteroatoms other than nitrogen, for example, hydroxylamine, t-butyloxycarbonyl amine and N-t-butyl hydroxylamine are nitrogen-containing reactants.

### Etching Processing Examples

In various embodiments, atomic layer etch (ALE) is used to etch substrates. Various embodiments involve oxidation combined with an ion-less oxide etch. This cycled two-step process etches in monolayer increments, resulting in a uniformly etched trench or feature and can be used to etch laterally. Methods are independent of feature size, shape, or 3-D aspects of the substrate because there is little to no re-deposition and each cycle is a self-limiting reaction such that the top, middle, and bottom of a trench etches at the same monolayer depth, thereby not altering the profile even during lateral etch. Disclosed embodiments may be used to fabricate source-drain regions of a transistor.

As an example, a conventional ALE cycle may include the following operations: (i) delivery of a reactant gas, (ii) purging of the reactant gas from the chamber, (iii) delivery of a removal gas and an optional plasma, and (iv) purging of the chamber. In some embodiments, etching may be performed nonconformally. The modification operation generally forms a thin, reactive surface layer with a thickness less than the un-modified material. In an example modification operation, a substrate may be chlorinated by introducing chlorine into the chamber. Chlorine is used as an example etchant species or etching gas, but it will be understood that a different etching gas may be introduced into the chamber. The etching gas may be selected depending on the type and chemistry of the substrate to be etched. A plasma may be ignited and chlorine reacts with the substrate for the etching process; the chlorine may react with the substrate or may be adsorbed onto the surface of the substrate. The species generated from a chlorine plasma can be generated directly by forming a plasma in the process chamber housing the substrate or they can be generated remotely in a process chamber that does not house the substrate, and can be supplied into the process chamber housing the substrate.

As also mentioned above, the etching process involves a plasma etch. This may involve introducing activated species (including radicals, ions and/or high energy molecules) from a remote plasma generator. In certain embodiments, the removal operation involves a fluorine-based plasma etch, e.g., a remote NF3 plasma etch. The extent of the etch-back is discussed further below, though in certain embodiments, about 10% of the deposited layer is removed. The flow of fluorine activated species (or other species depending on the removal chemistry) is then shut off. Typically, the process is complete at this point if the deposited thickness after etch-back is the desired total thickness. In certain embodiments, at least one additional deposition-removal cycle is performed to deposit the tungsten layer.

The removal operation may be any physical or chemical removal operation that can be used to remove a top portion of the as-deposited film. Etch chemistries that may be employed include fluorine-containing etch chemistries, including using xenon difluoride, molecular fluorine and nitrogen trifluoride. Bromine and chlorine-containing compounds, including nitrogen trichloride, molecular chlorine and molecular bromine. In certain embodiments, the etch may be a plasma etch. The plasma may be generated remotely or in the chamber. In a particular embodiment, NF3 is fed to a remote plasma generator. Activated species, including atomic fluorine, are generated within the remote plasma generator and flowed into the chamber for the chemical etch.

Etchant pressure has been found to affect film resistivity, with higher pressure resulting in lower resistivity. Using high partial pressure results in films having lower resistivity. The conventionally deposited film has a resistivity of almost 18 micro-ohm-cm, whereas the high NF3 film has a resistivity of less than 16 micro-ohm-cm—a greater than 20% improvement. In certain embodiments, the partial pressure of the etchant as introduced to a remote plasma generator is above 0.5 Torr, and as high as 80 Torr. In particular embodiments, the partial pressure of the etchant is about 1 Torr as flowed into the remote plasma generator, or deposition chamber.

Comparing the resistivity of the conventionally deposited films to that of etched films of comparable thicknesses (e.g., at about 400 Å and about 900 Å), the resistivity of the etched films is less than that of the conventionally deposited films. Resistivity improves for both high flow (high partial pressure) etchant as well as low flow (low partial pressure) etchant over conventionally deposited film. This is shown in the table below:

| | As-deposited | Final | Resistivity as- | Final |
|---|---|---|---|---|
| | Thickness | Thickness | deposited | resistivity |
| Process | (Å) | (Å) | (micro-ohm-cm) | (micro-ohm-cm) |
| Conventional | 1720 | 1720 | 15.5 | 15.5 |
| Dep-Low | 1940 | 1740 | 15 | 15 |
| NF3 Etch | | | | |
| Conventional | 1350 | 1350 | 17 | 17 |
| (estimated | | | | |
| from | | | | |
| trendline) | | | | |
| Dep-High | 1940 | 1350 | 15 | 14.3 |
| NF3 Etch | | | | |

With conventional deposition, there is an inverse relationship between resistivity and thickness: resistivity decreases with increasing thickness. Using the methods described herein however, it is possible to obtain low resistivity thin films. This process may be used to deposit thin films having low resistivity, with final thin film thickness ranging according to various embodiments, from 100 Å to 1000 Å. For thin films, the final film thickness may be between 10%-90% of the as-deposited film, i.e., as much as 90% of the as-deposited film may be removed to create the low resistivity thin film.

In addition to chemical etching, the top portion may be removed in certain embodiments by sputtering, e.g., with argon, or by a very soft chemical mechanical planarization (CMP) method such as touch CMP.

### Additional Apparatuses

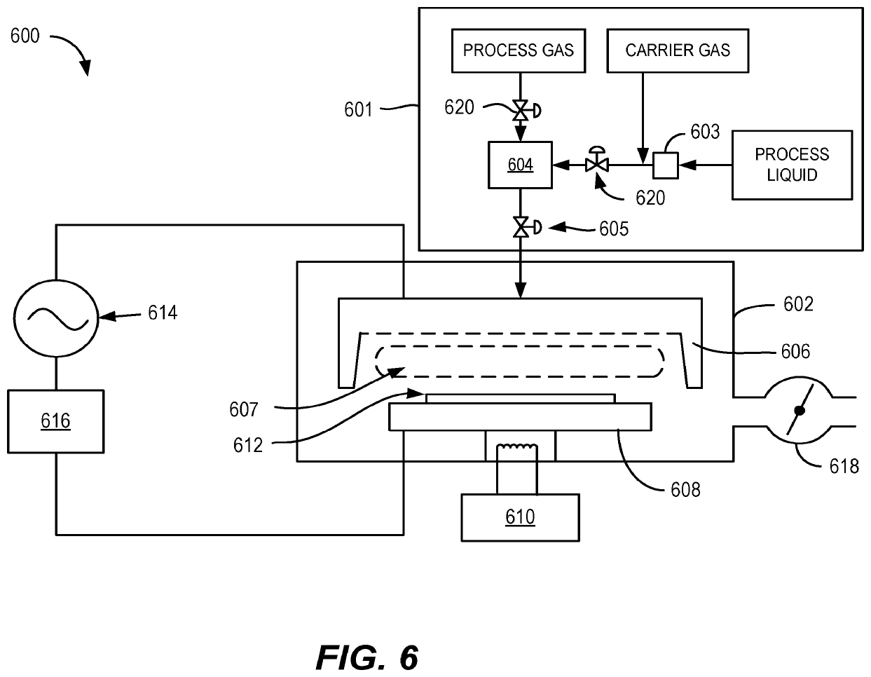

FIG. 6 schematically shows an embodiment of a process station 600 that may be used to deposit material using atomic layer deposition (ALD) and/or chemical vapor deposition (CVD), either of which may be plasma enhanced. For simplicity, the process station 600 is depicted as a standalone process station having a process chamber body 602 for maintaining a low-pressure environment. However, it will be appreciated that a plurality of process stations 600 may be included in a common process tool environment. Further, it will be appreciated that, in some embodiments, one or more hardware parameters of process station 600, including those discussed in detail below, may be adjusted programmatically by one or more computer controllers.

Process station 600 fluidly communicates with reactant delivery system 601 for delivering process gases to a distribution showerhead 606. Reactant delivery system 601 includes a mixing vessel 604 for blending and/or conditioning process gases for delivery to showerhead 606. One or more mixing vessel inlet valves 620 may control introduction of process gases to mixing vessel 604. Similarly, a showerhead inlet valve 605 may control introduction of process gasses to the showerhead 606.

Some reactants, like BTBAS, may be stored in liquid form prior to vaporization at and subsequent delivery to the process station. For example, the embodiment of FIG. 6 includes a vaporization point 603 for vaporizing liquid reactant to be supplied to mixing vessel 604. In some embodiments, vaporization point 603 may be a heated vaporizer. The reactant vapor produced from such vaporizers may condense in downstream delivery piping. Exposure of incompatible gases to the condensed reactant may create small particles. These small particles may clog piping, impede valve operation, contaminate substrates, etc. Some approaches to addressing these issues involve sweeping and/or evacuating the delivery piping to remove residual reactant. However, sweeping the delivery piping may increase process station cycle time, degrading process station throughput. Thus, in some embodiments, delivery piping downstream of vaporization point 603 may be heat traced. In some examples, mixing vessel 604 may also be heat traced. In one non-limiting example, piping downstream of vaporization point 603 has an increasing temperature profile extending from approximately 100° C. to approximately 150° C. at mixing vessel 604.

In some embodiments, reactant liquid may be vaporized at a liquid injector. For example, a liquid injector may inject pulses of a liquid reactant into a carrier gas stream upstream of the mixing vessel. In one scenario, a liquid injector may vaporize reactant by flashing the liquid from a higher pressure to a lower pressure. In another scenario, a liquid injector may atomize the liquid into dispersed microdroplets that are subsequently vaporized in a heated delivery pipe. It will be appreciated that smaller droplets may vaporize faster than larger droplets, reducing a delay between liquid injection and complete vaporization. Faster vaporization may reduce a length of piping downstream from vaporization point 603. In one scenario, a liquid injector may be mounted directly to mixing vessel 604. In another scenario, a liquid injector may be mounted directly to showerhead 606.

In some embodiments, a liquid flow controller upstream of vaporization point 603 may be provided for controlling a mass flow of liquid for vaporization and delivery to process station 600. For example, the liquid flow controller (LFC) may include a thermal mass flow meter (MFM) located downstream of the LFC. A plunger valve of the LFC may then be adjusted responsive to feedback control signals provided by a proportional-integral-derivative (PID) controller in electrical communication with the MFM. However, it may take one second or more to stabilize liquid flow using feedback control. This may extend a time for dosing a liquid reactant. Thus, in some embodiments, the LFC may be dynamically switched between a feedback control mode and a direct control mode. In some embodiments, the LFC may be dynamically switched from a feedback control mode to a direct control mode by disabling a sense tube of the LFC and the PID controller.

Showerhead 606 distributes process gases toward substrate 612. In the embodiment shown in FIG. 6, substrate 612 is located beneath showerhead 606, and is shown resting on a pedestal 608. It will be appreciated that showerhead 606 may have any suitable shape, and may have any suitable number and arrangement of ports for distributing processes gases to substrate 612.

In some embodiments, a microvolume 607 is located beneath showerhead 606. Performing an ALD and/or CVD process in a microvolume rather than in the entire volume of a process station may reduce reactant exposure and sweep times, may reduce times for altering process conditions (e.g., pressure, temperature, etc.), may limit an exposure of process station robotics to process gases, etc. Example microvolume sizes include, but are not limited to, volumes between 0.1 liter and 2 liters. This microvolume also impacts productivity throughput. While deposition rate per cycle drops, the cycle time also simultaneously reduces. In certain cases, the effect of the latter is dramatic enough to improve overall throughput of the module for a given target thickness of film.

In some embodiments, pedestal 608 may be raised or lowered to expose substrate 612 to microvolume 607 and/or to vary a volume of microvolume 607. For example, in a substrate transfer phase, pedestal 608 may be lowered to allow substrate 612 to be loaded onto pedestal 608. During a deposition process phase, pedestal 608 may be raised to position substrate 612 within microvolume 607. In some embodiments, microvolume 607 may completely enclose substrate 612 as well as a portion of pedestal 608 to create a region of high flow impedance during a deposition process.

Optionally, pedestal 608 may be lowered and/or raised during portions the deposition process to modulate process pressure, reactant concentration, etc., within microvolume 607. In one scenario where process chamber body 602 remains at a base pressure during the deposition process, lowering pedestal 608 may allow microvolume 607 to be evacuated. Example ratios of microvolume to process chamber volume include, but are not limited to, volume ratios between 1:600 and 1:10. It will be appreciated that, in some embodiments, pedestal height may be adjusted programmatically by a suitable computer controller.

In another scenario, adjusting a height of pedestal 608 may allow a plasma density to be varied during plasma activation and/or treatment cycles included in the deposition process. At the conclusion of the deposition process phase, pedestal 608 may be lowered during another substrate transfer phase to allow removal of substrate 612 from pedestal 608.

While the example microvolume variations described herein refer to a height-adjustable pedestal, it will be appreciated that, in some embodiments, a position of showerhead 606 may be adjusted relative to pedestal 608 to vary a volume of microvolume 607. Further, it will be appreciated that a vertical position of pedestal 608 and/or showerhead 606 may be varied by any suitable mechanism within the scope of the present disclosure. In some embodiments, pedestal 608 may include a rotational axis for rotating an orientation of substrate 612. It will be appreciated that, in some embodiments, one or more of these example adjustments may be performed programmatically by one or more suitable computer controllers.

Returning to the embodiment shown in FIG. 6, showerhead 606 and pedestal 608 electrically communicate with RF power supply 614 and matching network 616 for powering a plasma. In some embodiments, the plasma energy may be controlled by controlling one or more of a process station pressure, a gas concentration, an RF source power, an RF source frequency, and a plasma power pulse timing. For example, RF power supply 614 and matching network 616 may be operated at any suitable power to form a plasma having a desired composition of radical species. Examples of suitable powers are included above. Likewise, RF power supply 614 may provide RF power of any suitable frequency. In some embodiments, RF power supply 614 may be configured to control high- and low-frequency RF power sources independently of one another. Example low-frequency RF frequencies may include, but are not limited to, frequencies between 50 kHz and 600 kHz. Example high-frequency RF frequencies may include, but are not limited to, frequencies between 1.8 MHz and 2.45 GHz. It will be appreciated that any suitable parameters may be modulated discretely or continuously to provide plasma energy for the surface reactions. In one non-limiting example, the plasma power may be intermittently pulsed to reduce ion bombardment with the substrate surface relative to continuously powered plasmas.

In some embodiments, the plasma may be monitored in-situ by one or more plasma monitors. In one scenario, plasma power may be monitored by one or more voltage, current sensors (e.g., VI probes). In another scenario, plasma density and/or process gas concentration may be measured by one or more optical emission spectroscopy sensors (OES). In some embodiments, one or more plasma parameters may be programmatically adjusted based on measurements from such in-situ plasma monitors. For example, an OES sensor may be used in a feedback loop for providing programmatic control of plasma power. It will be appreciated that, in some embodiments, other monitors may be used to monitor the plasma and other process characteristics. Such monitors may include, but are not limited to, infrared (IR) monitors, acoustic monitors, and pressure transducers.

In some embodiments, the plasma may be controlled via input/output control (IOC) sequencing instructions. In one example, the instructions for setting plasma conditions for a plasma process phase may be included in a corresponding plasma activation recipe phase of a deposition process recipe. In some cases, process recipe phases may be sequentially arranged, so that all instructions for a deposition process phase are executed concurrently with that process phase. In some embodiments, instructions for setting one or more plasma parameters may be included in a recipe phase preceding a plasma process phase. For example, a first recipe phase may include instructions for setting a flow rate of an inert and/or a reactant gas, instructions for setting a plasma generator to a power set point, and time delay instructions for the first recipe phase. A second, subsequent recipe phase may include instructions for enabling the plasma generator and time delay instructions for the second recipe phase. A third recipe phase may include instructions for disabling the plasma generator and time delay instructions for the third recipe phase. It will be appreciated that these recipe phases may be further subdivided and/or iterated in any suitable way within the scope of the present disclosure.

In some deposition processes, plasma strikes last on the order of a few seconds or more in duration. In certain implementations, much shorter plasma strikes may be used. These may be on the order of 10 ms to 1 second, typically, about 20 to 80 ms, with 50 ms being a specific example. Such very short RF plasma strikes require extremely quick stabilization of the plasma. To accomplish this, the plasma generator may be configured such that the impedance match is set preset to a particular voltage, while the frequency is allowed to float. Conventionally, high-frequency plasmas are generated at an RF frequency at about 13.56 MHz. In various embodiments disclosed herein, the frequency is allowed to float to a value that is different from this standard value. By permitting the frequency to float while fixing the impedance match to a predetermined voltage, the plasma can stabilize much more quickly, a result which may be important when using the very short plasma strikes associated with some types of deposition cycles.

In some embodiments, pedestal 608 may be temperature controlled via heater 610. Further, in some embodiments, pressure control for deposition process station 600 may be provided by butterfly valve 618. As shown in the embodiment of FIG. 6, butterfly valve 618 throttles a vacuum provided by a downstream vacuum pump (not shown). However, in some embodiments, pressure control of process station 600 may also be adjusted by varying a flow rate of one or more gases introduced to process station 600.

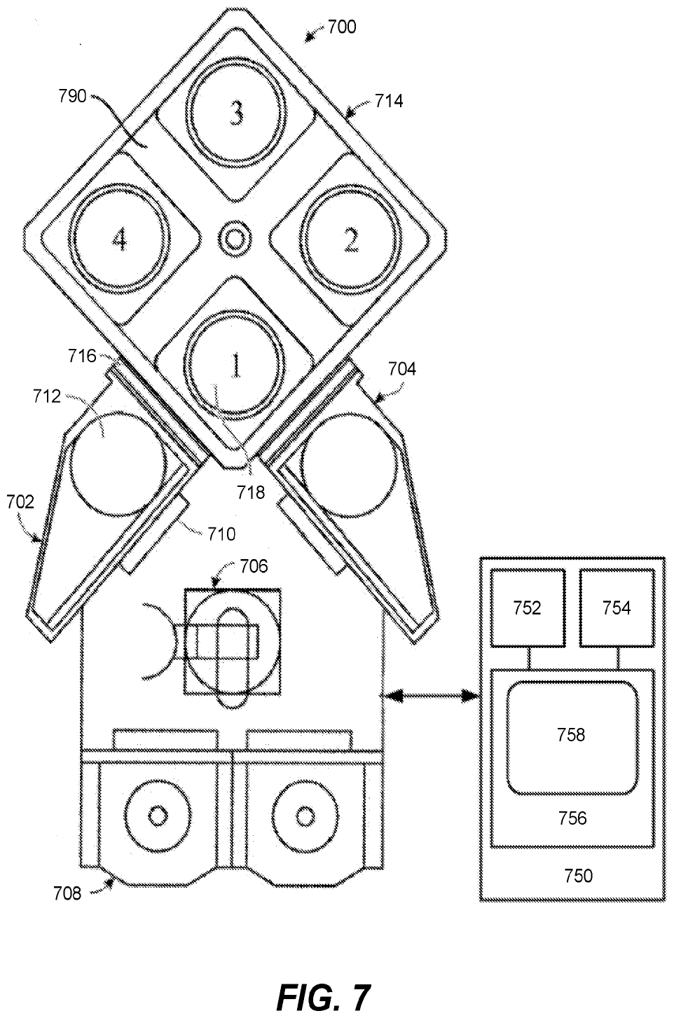

FIG. 7 shows a schematic view of an embodiment of a multi-station processing tool 700 with an inbound load lock 702 and an outbound load lock 704, either or both of which may comprise a remote plasma source. A robot 706, at atmospheric pressure, is configured to move wafers from a cassette loaded through a pod 708 into inbound load lock 702 via an atmospheric port 710. A wafer is placed by the robot 706 on a pedestal 712 in the inbound load lock 702, the atmospheric port 710 is closed, and the load lock is pumped down. Where the inbound load lock 702 comprises a remote plasma source, the wafer may be exposed to a remote plasma treatment in the load lock prior to being introduced into a processing chamber 714. Further, the wafer also may be heated in the inbound load lock 702 as well, for example, to remove moisture and adsorbed gases. Next, a chamber transport port 716 to processing chamber 714 is opened, and another robot (not shown) places the wafer into the reactor on a pedestal of a first station shown in the reactor for processing. While the embodiment depicted in FIG. 4 includes load locks, it will be appreciated that, in some embodiments, direct entry of a wafer into a process station may be provided.

The depicted processing chamber 714 comprises four process stations, numbered from 1 to 4 in the embodiment shown in FIG. 7. Each station has a heated pedestal (shown at 718 for station 1), and gas line inlets. It will be appreciated that in some embodiments, each process station may have different or multiple purposes. While the depicted processing chamber 714 comprises four stations, it will be understood that a processing chamber according to the present disclosure may have any suitable number of stations. For example, in some embodiments, a processing chamber may have five or more stations, while in other embodiments a processing chamber may have three or fewer stations.

FIG. 7 also depicts an embodiment of a wafer handling system 790 for transferring wafers within processing chamber 714. In some embodiments, wafer handling system 790 may transfer wafers between various process stations and/or between a process station and a load lock. It will be appreciated that any suitable wafer handling system may be employed. Non-limiting examples include wafer carousels and wafer handling robots. FIG. 7 also depicts an embodiment of a system controller 750 employed to control process conditions and hardware states of process tool 700. System controller 750 may include one or more memory devices 756, one or more mass storage devices 754, and one or more processors 752. Processor 752 may include a CPU or computer, analog and/or digital input/output connections, stepper motor controller boards, etc.

In some embodiments, system controller 750 controls all of the activities of process tool 700. System controller 750 executes system control software 758 stored in mass storage device 754, loaded into memory device 756, and executed on processor 752. System control software 758 may include instructions for controlling the timing, mixture of gases, chamber and/or station pressure, chamber and/or station temperature, purge conditions and timing, wafer temperature, RF power levels, RF frequencies, substrate, pedestal, chuck and/or susceptor position, and other parameters of a particular process performed by process tool 700. System control software 758 may be configured in any suitable way. For example, various process tool component subroutines or control objects may be written to control operation of the process tool components necessary to carry out various process tool processes in accordance with the disclosed methods. System control software 758 may be coded in any suitable computer readable programming language.

In some embodiments, system control software 758 may include input/output control (IOC) sequencing instructions for controlling the various parameters described above. For example, each phase of a PEALD process may include one or more instructions for execution by system controller 750. The instructions for setting process conditions for a PEALD process phase may be included in a corresponding PEALD recipe phase. In some embodiments, the PEALD recipe phases may be sequentially arranged, so that all instructions for a PEALD process phase are executed concurrently with that process phase.

Other computer software and/or programs stored on mass storage device 754 and/or memory device 756 associated with system controller 750 may be employed in some embodiments. Examples of programs or sections of programs for this purpose include a substrate positioning program, a process gas control program, a pressure control program, a heater control program, and a plasma control program.

A substrate positioning program may include program code for process tool components that are used to load the substrate onto pedestal 718 and to control the spacing between the substrate and other parts of process tool 700.

A process gas control program may include code for controlling gas composition and flow rates and optionally for flowing gas into one or more process stations prior to deposition in order to stabilize the pressure in the process station. The process gas control program may include code for controlling gas composition and flow rates within any of the disclosed ranges. A pressure control program may include code for controlling the pressure in the process station by regulating, for example, a throttle valve in the exhaust system of the process station, a gas flow into the process station, etc. The pressure control program may include code for maintaining the pressure in the process station within any of the disclosed pressure ranges.

A heater control program may include code for controlling the current to a heating unit that is used to heat the substrate. Alternatively, the heater control program may control delivery of a heat transfer gas (such as helium) to the substrate. The heater control program may include instructions to maintain the temperature of the substrate within any of the disclosed ranges.

A plasma control program may include code for setting RF power levels and frequencies applied to the process electrodes in one or more process stations, for example using any of the RF power levels disclosed herein. The plasma control program may also include code for controlling the duration of each plasma exposure.

In some embodiments, there may be a user interface associated with system controller 750. The user interface may include a display screen, graphical software displays of the apparatus and/or process conditions, and user input devices such as pointing devices, keyboards, touch screens, microphones, etc.

In some embodiments, parameters adjusted by system controller 750 may relate to process conditions. Non-limiting examples include process gas composition and flow rates, temperature, pressure, plasma conditions (such as RF power levels, frequency, and exposure time), etc. These parameters may be provided to the user in the form of a recipe, which may be entered utilizing the user interface.

Signals for monitoring the process may be provided by analog and/or digital input connections of system controller 750 from various process tool sensors. The signals for controlling the process may be output on the analog and digital output connections of process tool 700. Non-limiting examples of process tool sensors that may be monitored include mass flow controllers, pressure sensors (such as manometers), thermocouples, etc. Appropriately programmed feedback and control algorithms may be used with data from these sensors to maintain process conditions.

Any suitable chamber may be used to implement the disclosed embodiments. Example deposition apparatuses include, but are not limited to, apparatus from the ALTUS® product family, the VECTOR® product family, and/or the SPEED® product family, each available from Lam Research Corp., of Fremont, Calif., or any of a variety of other commercially available processing systems. Two or more of the stations may perform the same functions. Similarly, two or more stations may perform different functions. Each station can be designed/configured to perform a particular function/method as desired.

System controller 750 may provide program instructions for implementing the above-described deposition processes. The program instructions may control a variety of process parameters, such as DC power level, RF bias power level, pressure, temperature, etc. The instructions may control the parameters to operate in-situ deposition of film stacks according to various embodiments described herein.

The system controller 750 will typically include one or more memory devices and one or more processors configured to execute the instructions so that the apparatus will perform a method in accordance with disclosed embodiments. Machine-readable media containing instructions for controlling process operations in accordance with disclosed embodiments may be coupled to the system controller 750.

In some implementations, the system controller 750 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The system controller 750, depending on the processing conditions and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the system controller 750 refers to electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the system controller 750 in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The system controller 750, in some implementations, may be a part of or coupled to a computer that is integrated with, coupled to the system, otherwise networked to the system, or a combination thereof. For example, the system controller 750 may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the system controller 750 receives instructions in the form of data, which specify parameters for each of the processing steps to be performed during one or more operations. It should be understood that the parameters may be specific to the type of process to be performed and the type of tool that the system controller 750 is configured to interface with or control. Thus, as described above, the system controller 750 may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

The controller described herein may have program instructions for executing any and all of the example processes and techniques described herein. For example, the apparatuses may have a controller with a memory storing instructions for depositing, while no wafers are present in a reaction chamber having a plurality of interior surfaces, a first layer of protective material onto the plurality of interior surfaces of the reaction chamber, processing, after the depositing the first layer of protective material, a portion of a batch of wafers within a reaction chamber, measuring an amount of the first material in the reaction chamber during the processing the portion of the batch of wafers, or on one of the wafers in the portion of the batch of wafers, determining that the first amount exceeds a threshold, and depositing, in response to the determination that the first amount exceeds the threshold and while no wafers are present in the reaction chamber, a second layer of protective material onto the plurality of interior surfaces of the reaction chamber. This may also include instructions for performing all of the operations of the techniques described above in FIGS. 2, 3, and 4.

### Experimental

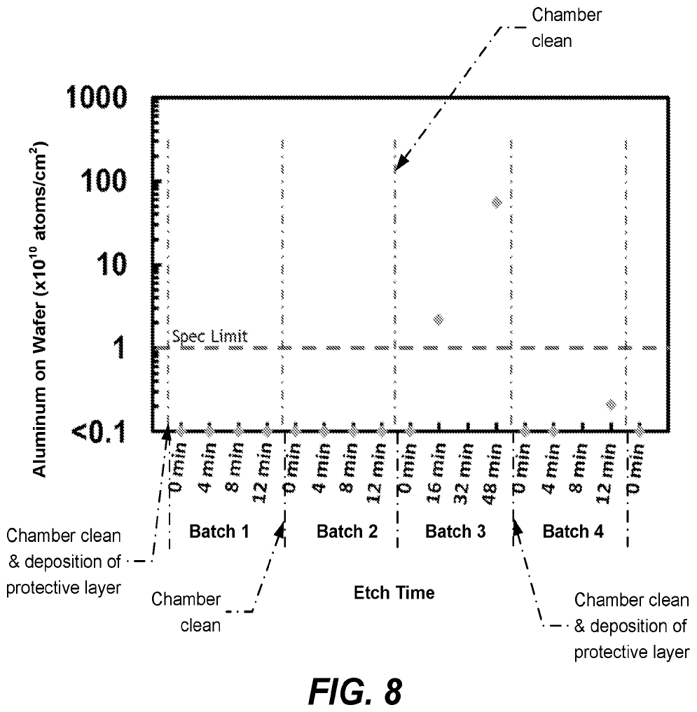

As noted above, a subsequent deposition of protective material can help recover from the etching or corrosion of the reaction chamber's interior surfaces and the previously deposited protective materials. FIG. 8 depicts experimental data of aluminum measured on wafers after various amounts of etching and chamber cleans are performed in a reaction chamber having aluminum interior surfaces and a protective material deposited thereon as described herein. As can be seen, four batches of wafers undergo etching and the reaction chamber is cleaned after each batch. The etching includes dry etching with SOCl₂ and the chamber clean uses nitrogen trifluoride (NF₃). At various times during these batches, e.g., at 0, 4, 8, 12, 16, 32, and 48 minutes of total etching time the amount of aluminum is measured on one of the wafers in the batch and plotted on this graph. A protective coating of silicon oxide (SiO₂) is deposited at the beginning of the first batch and again after the third batch. This data shows that during the first and second batches there was no measured aluminum on wafers above the threshold limit, which is 1×10¹⁰ atoms/cm². In these two batches, the deposited SiO₂ protective material prevented the reaction chamber from being etched. During the third batch, however, aluminum was measured on one wafer after 16 minutes and on another wafer at 48 minutes in an amount that exceeded the threshold. This indicates that some of the protective material had been etched away and exposed some interior surface of the reaction chamber which was also being etched and releasing aluminum in the reaction chamber interior volume and onto the wafer. After the processing of this batch was completed and the cleaning operation after this batch was performed, a second, subsequent deposition of the SiO₂ protective material was performed which, as seen in the fourth batch, prevented the reaction chamber from being etched above the threshold limit and thus caused the reaction chamber to recover from the etching.

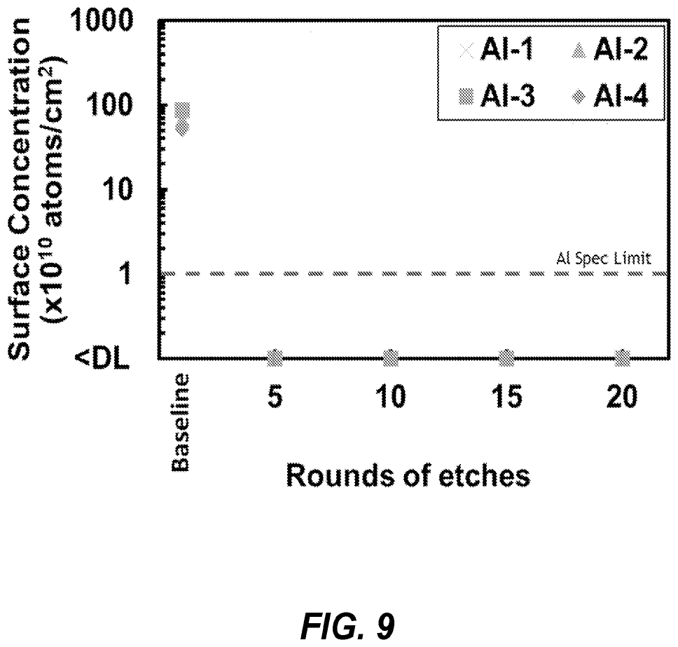

FIG. 9 depicts other experimental data of aluminum measured on wafers after various amounts of etching are performed in a reaction chamber having aluminum interior surfaces and a protective coating deposited thereon as described herein. Here, wafer surface concentration of aluminum is the vertical axis and rounds of etches are on the horizontal axis. The etching is again dry etching. For the baseline etching, no protective material was deposited on the interior surfaces of the reaction chamber and as can be seen, after 12 minutes of dry etching with SOCl₂ and 10 minutes of NF₃ etching were performed, the aluminum threshold was exceeded by 100×. After the baseline, a SiO₂ protective material of 5,000 Å was deposited onto the reaction chamber's interior surfaces and 20 rounds of etching were performed; each round of etching included 12 minutes of dry etching with SOCl₂ and 10 minutes of NF₃ etching. After each round of etching, the SiO₂ protective material was again deposited on the reaction chamber's interior surfaces. After 20 rounds of etching and depositing operations, no aluminum was measured on the wafers thus indicating that the protective material prevented the reaction chamber's interior surfaces from being etched by the etching operations.

### CONCLUSION

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

The following sample claims are provided for further illustration of certain embodiments of the disclosure. The disclosure is not necessarily limited to these embodiments.

What is claimed is:

1. A method comprising:
depositing, while no wafers are present in a reaction chamber having a plurality of interior surfaces, a first layer of protective material onto the plurality of interior surfaces of the reaction chamber, wherein the plurality of interior surfaces comprise a first material;
processing, after depositing the first layer of protective material, a portion of a batch of wafers within a reaction chamber;
measuring an amount of the first material in the reaction chamber during the processing the portion of the batch of wafers, or on one of the wafers in the portion of the batch of wafers;
determining that the first amount exceeds a threshold; and
depositing, in response to the determination that the first amount exceeds the threshold and while no wafers are present in the reaction chamber, a second layer of protective material onto the plurality of interior surfaces of the reaction chamber.

2. The method of claim 1, further comprising:
processing, after depositing the second layer of protective material, a second portion of the batch of wafers within the reaction chamber.

3. The method of claim 1, further comprising cleaning, before depositing the second layer of protective material, the reaction chamber.

4. The method of claim 3, wherein the depositing the second layer of protective material further includes depositing the second layer of protective material onto the first layer of material and onto the plurality of interior surfaces of the reaction chamber.

5. The method of claim 1, wherein the measuring further includes measuring the amount of the first material in the reaction chamber during a processing operation during the processing the portion of the batch of wafers.

6. The method of claim 5, wherein the measuring further includes measuring the amount of the first material in the reaction chamber during the processing operation by using a residual gas analyzer or a spectroscope.

7. The method of claim 1, wherein the measuring further includes measuring the amount of the first material on one of the wafers in the portion of the wafers.

8. The method of claim 1, wherein the protective material comprises silicon oxide.

9. The method of claim 1, wherein the first material comprises aluminum or aluminum alloy.

10. The method of claim 1, wherein the processing includes etching operations.

11. The method of claim 1, wherein the processing includes deposition operations.

12. The method of claim 1, wherein the processing does not include a chamber cleaning operation.

13. The method of claim 1, wherein the depositing the protective material onto the plurality of interior surfaces of the reaction chamber is performed by atomic layer deposition.

14. A method comprising:
depositing, while no wafers are present in a reaction chamber, a layer of protective material onto a plurality of interior surfaces of the reaction chamber, wherein the plurality of interior surfaces comprise a first material;
processing a portion of a batch of wafers within the reaction chamber, the processing uses a process gas that is capable of etching the first material of the plurality of interior surfaces at a first etch rate during the processing at a first set of processing conditions, wherein the process gas etches the protective material at a second etch rate during the processing at the first set of processing conditions, and wherein the second etch rate is at least 20 times less than the first etch rate.

15. The method of claim 14, further comprising:
depositing, after processing the portion of the batch of wafers and while no wafers are present in the reaction chamber, a second layer of protective material onto the plurality of interior surfaces of the reaction chamber; and
processing, after depositing the second layer of protective material, a second portion of the batch of wafers within the reaction chamber.

16. The method of claim 15, further comprising cleaning, before depositing the second layer of protective material, the reaction chamber.

17. The method of claim 16, Wherein the depositing the second layer of protective material further includes depositing the second layer of protective material onto the first layer of material and onto the plurality of interior surfaces of the reaction chamber.

18. The method of claim 14, wherein the protective layer comprises silicon oxide.

19. The method of claim 14, wherein the first material comprises aluminum or aluminum alloy.

20. An apparatus for use in semiconductor processing, the apparatus comprising:
a reaction chamber having a top with a top surface, side walls with wall surfaces, and a bottom with a bottom surface, and an internal volume partially defined by the top, the side walls, and the bottom,
a substrate support having substrate support exterior surfaces;
a showerhead having showerhead exterior surfaces; and
a protective coating of material, wherein:
the substrate support and the showerhead are positioned within the internal volume of the reaction chamber,
the top surface, the wall surfaces, the bottom surface, the substrate support exterior surfaces, and the showerhead exterior surfaces are comprised of a first material that comprises a metal, and
the protective coating is on and in direct contact with the top surface, the wall surfaces, the bottom surface, the substrate support exterior surfaces, and the showerhead exterior surfaces.
